(19) United States
(12) Patent Application Publication
(10) Pub. No.: US 2007/0035363 A1
(43) Pub. Date: Feb. 15, 2007

(54) Electromagnetic delay line inductance element

(75) Inventor: Masaaki Kameya, Kawasaki-shi (JP)

Correspondence Address: FOLEY AND LARDNER LLP;SUITE 500, 3000 K STREET NW, WASHINGTON, DC, 20007, US

(73) Assignee: ELMEC CORPORATION, Kawasaki-shi (JP)

(21) Appl. No.: 10/578,143

(22) PCT Filed: Nov. 2, 2004
(86) PCT No.: PCT/JP04/16271

§ 371 Date: Jun. 6, 2006

(30) Foreign Application Priority Data
Nov. 4, 2003 (JP) 2003-374190

(51) Int. Cl. H03H 7/18

(52) U.S. Cl. 333/140

(57) ABSTRACT

To provide an inductance element of a lumped constant type electromagnetic delay line which can easily be made as an ultra-small chip shape and obtain a preferable connection state at each section. Spiral-shaped inductors L0B, L4A, and L4B are formed on a first insulating substrate 15, and inductors L4A and L4B are connected in series. Spiral-shaped inductors L1, L3, and L5 are formed on a second and third insulating substrates 22 and 33. Spiral-shaped inductors L2A, L2B, and L6A are formed on a fourth insulating substrate 41, and the inductors L2A and L2B are connected in series. The first to fourth insulating substrates 15 to 41 are stacked on one another, and the inductors L0B to L6A are vertically connected. The inductors L2A and L2B, and L4A and L4B are divided into two portions in horizontal directions to form one section, and connected with positive coupling to the preceding and the following sections not divided in the horizontal direction.

### 1. FIELD OF THE INVENTION

The present invention relates to an inductance element of an electromagnetic delay line, and particularly to an improvement of the inductance element suitable for use in a lumped constant type ultra-small electromagnetic delay line.

### 2. DESCRIPTION OF THE RELATED ART

As an ultra-small electromagnetic delay line of this kind, by using a microstrip line, a simple structure can be easily realized for obtaining a delay time of ins or less.

However, in order to realize the delay time of ins or more, a line length of the microstrip line needs to be increased in proportion to the delay time thus increased. This increases DC resistance value of the microstrip line, to increase attenuation in a signal, making it difficult to be put into practical use.

Therefore, as the electromagnetic delay line featuring the delay time of ins or more, a distribution constant type structure shown in FIG. 4 is proposed.

Specifically, a spiral-shaped inductance element 3 is formed on one side of a small quadrilateral insulating substrate 1 through thick film printing, and a ground electrode 7 is formed on an opposite face of another same-shaped insulating substrate 5. The insulating substrate 1 is stacked on the insulating substrate 5, so that the inductance element 3 and the ground electrode 7 are arranged to face each other through the insulating substrate 1. An external connecting pattern 11 is formed on one side of another insulating substrate 9 having the same shape as the insulating substrate 1, and this is stacked on the insulating substrate 1. In the center portion of the insulating substrate 9, the external connecting pattern 11 is connected to a connection pad S1 of the center portion of the inductance element 3 through a via hole (through hole) 13. Patent document 1 provides this kind of the inductance element of the electromagnetic delay line.

A peripheral tip T1 of the inductance element 3 extends to an edge portion of the insulating substrate 9, and functions as an input/output electrode in the same manner as the external connecting pattern 11.

In the electromagnetic delay line with this structure, the inductance element 3 is arranged to face the ground electrode 7 through the insulating substrate 1, thereby forming a distributed capacitance. Therefore, the inductance element 3 and the distributed capacitance thus formed allow the electromagnetic delay line to function as a distribution constant type electromagnetic delay line.

The electromagnetic delay line with this structure has an advantage that inductance component per unit length of a conductor is larger than the aforementioned microstrip line, and DC resistance per each delay time is reduced compared to that of the microstrip line, and has a simple structure. However, delay characteristic of this electromagnetic delay line is deemed as being deteriorated compared to that of the microstrip line.

Further, when the delay time is increased by increasing the number of turns of the inductance element 3, the delay characteristic is significantly deteriorated. Therefore, the electromagnetic delay line with delay time of about 2 ns can be put into practical use, particularly as a chip-shaped ultra-small electromagnetic delay line.

From this viewpoint, a lumped constant type electromagnetic delay line is preferable for obtaining a large delay time.

Although not shown, a publicly known lumped constant type electromagnetic delay line is so structure that a plurality of inductors L are connected in series, having electroconductive wire wound around a magnetic bobbin prescribed number of times for obtaining delay time of about 30 ns or more, having electroconductive wire wound around a non-magnetic bobbin prescribed number of times for obtaining delay time of about 30 ns or less, and capacities C are vertically connected to each connection point in a ladder shape. An equivalent circuit is shown in FIG. 5.

In the lumped constant type electromagnetic delay line with this structure, generally a plurality of inductors L are physically arranged with a fixed space. Therefore, electromagnetic coupling inevitably occurs between each inductor L that forms each section

In the aforementioned electromagnetic coupling, preferably coupling coefficients a1, a3, . . . between inductors L that couple to each other at odd-order are positive, and coupling coefficients a2, a4, . . . between inductors L that couple to each other at even-order are negative. It is known that the value of the coupling coefficient a1 is about 0.17, a2 is about −0.028, and a3 is about 0.012, and the absolute value of a1 is largest, and an optimal value becomes smaller along with an increase of order. As for the influence on the delay characteristic, the influence of the coupling coefficient a1 between adjacent inductors L is largest, and the influence of a2, a3, . . . becomes smaller in this order.

Therefore, in the lumped constant type electromagnetic delay line, the magnetic bobbin or the non-magnetic bobbin needs to be arranged so as to obtain the aforementioned coupling state between inductors L.

(Patent document 1)

Japanese Patent Laid Open No. 05-29819

### PROBLEM TO BE SOLVED

However, for example, when the chip-shaped ultra-small electromagnetic delay line is constituted, or when the electromagnetic delay line is monolithic integrated on a semiconductor element substrate, a shape becomes excessively large when the inductors L are connected in series, with electroconductive wire wound around the magnetic bobbin or the hollow core bobbin. Therefore, the structure is forced to be constituted in such a way that a plurality of spiral-shaped inductors are formed in the horizontal direction on one side of the insulating substrate through thick film printing or other publicly-known method.

However, when the plurality of spiral-shaped inductors are formed in the horizontal direction on one side of the insulating substrate and the inductance element for electromagnetic delay line is formed, the coupling state between each section is not the aforementioned preferable state, and thus a desired delay characteristic can be hardly achieved.

Specifically, in the inductance element wherein the plurality of spiral-shaped inductors are formed in the horizontal direction and connected in series, it is significantly difficult to set the aforementioned coupling coefficient a1 at 0.05 or more even if the adjacent inductors which are arranged side by side are approached to each other as much as possible, and no other value but a far smaller value than the optimal value 0.17 of the coupling coefficient a1 is obtained.

In addition, the delay characteristic is mostly affected by the value of the coupling coefficient a1. Therefore, an improvement of the delay characteristic is hardly expected when the value of the coupling coefficient a1 is about 0.05.

When two spiral-shaped inductors are arranged so as to be vertically stacked on one another on both sides of the insulating substrate, a large coupling coefficient a1 can be obtained. However, in this case, conversely the coupling coefficient is excessively large.

For example, the spiral-shaped inductors of two turns are constituted at 1 mm corner region, and when these inductors are vertically arranged, the coupling coefficient becomes large to be set at about 0.6 in a case of 0.05 mm section, and it is necessary to set the section at about 0.35 mm for obtaining the aforementioned coupling coefficient of about 0.17. In other words, it is necessary to form the spiral-shaped inductors of adjacent sections on both sides of the insulating substrate with thickness of 0.35 mm.

However, when the chip-shaped lumped constant type delay line is constituted, a required capacitance is also formed on the insulating substrate. This means that the capacitance is also stacked on the insulating substrate on which the spiral-shaped inductors are formed. Further, the insulating substrate of 0.35 mm thickness is used. Therefore, the whole body becomes a thick multi-layer structure, making it difficult to obtain a chip-shaped ultra-small electronic component, for example.

Therefore, after various studies and experiments are conducted by the inventor of the present invention, it is found that a preferable coupling state of the aforementioned lumped constant type electromagnetic delay line can be obtained by arranging the inductors of each section in such a manner that the inductors of a part that forms one section of the lumped constant type electromagnetic delay line is divided into a first and second spiral-shaped inductors in the horizontal direction, and the second inductor of the preceding section is arranged in a vertical positional relation with the inductor of the section just after that in a profile of positive connection, and the first inductor of the preceding section is arranged in a vertical positional relation with the inductor of the further preceding section in a profile of positive connection, and such a relation continues thereafter.

In view of the above-described circumstances, the present invention is provided, and an object of the present invention is to provide a lumped constant type electromagnetic delay line which is easily made as an ultra-small chip shape, easily obtaining a preferable coupling state of each section, capable of enlarging the delay time per prescribed unit area, and capable of easily obtaining a desired delay characteristic.

### SOLVING MEANS

In order to solve the above-described problem, the inductance element of the present invention is constituted in such a manner that in the lumped constant type electromagnetic delay line having a plurality of sections formed of the inductance element which is formed by connecting a plurality of inductors in series, and capacities which are vertically connected to each connection point in a ladder shape, each inductor is formed in a spiral shape, and in the inductors of one section, the section divided and arranged into the first and second inductors in the horizontal direction and the section not divided are alternately and vertically connected. The first inductor is connected with positive coupling to the preceding inductor not divided in the vertical positional relation in series. The second inductor of this section is connected with positive coupling to the following inductor of the section not divided in the vertical positional relation in series.

The present invention is also constituted in such a way that the inductors of two sections formed between the section not divided in the horizontal direction, and the preceding and the following section divided in the horizontal direction, with the section not divided placed therebetween, are connected with positive coupling in the vertical relation, and this structure is defined as one inductance unit. In addition, a plurality of inductance units thus formed are vertically connected and adjacent inductance units can be dispersed and arranged in first, second . . . virtual lines.

### ADVANTAGE OF THE INVENTION

According to the present invention thus constituted, each inductor of one section of the electromagnetic delay line is formed in a spiral shape, and each inductor of one section is alternately and vertically connected between the section divided into the first and second inductors in the horizontal direction and the section not divided, and the first inductor is connected with positive coupling to the preceding inductor not divided in the vertical positional relation in series. The second inductor of this section is connected with positive coupling to the following inductor of the section not divided in the vertical positional relation in series. Therefore, the inductance element can easily be made ultra-small, and a connection state between each section is easily made to be a preferable state. When the electromagnetic delay line is constituted, the delay time per specified unit area can be increased, and a desired delay characteristic can be easily obtained.

Then, the arrangement of the inductors of two sections which are connected with positive coupling in the vertical positional relation is defined as one inductance unit. These inductance units are vertically connected and the adjacent inductance units are dispersed and arranged in the first, second, . . . virtual lines. With this structure, it becomes easy to form a plurality of sections, while obtaining a preferable coupling coefficient, and an increased delay time is realized.

### BEST MODES FOR CARRYING OUT THE INVENTION

The preferred embodiments of an inductance element of an electromagnetic delay line of the present invention will be explained hereunder, with reference to the drawings. The same signs and numerals are assigned to the part in common with the conventional art.

FIG. 1 and FIG. 2 are exploded perspective view showing the embodiments of the inductance element according to the present invention and its equivalent circuit.

In FIG. 1, a first insulating substrate 15 is formed in an appearance of a slender thin plate from a publicly-known dielectric body, and three inductors L0B, L4A, and L4B are formed on its one side (upper surface).

Inductors L0B, LA4, and L4B are respectively formed into a quadrilateral spiral shape and alternately wound reversely, and also linearly arranged in a longitudinal direction of the first insulating substrate 15 at prescribed sections.

The peripheral tip of the inductor L0B is connected to an input terminal 17 at a tip part of one side of the longitudinal direction of the first insulating substrate 15, and the tip part of its center side is extended through up to an opposite side (lower surface) of the first insulating substrate 15 through a via hole 19.

The peripheral tips of the inductor L4A adjacent to the inductor L0B and the inductor L4B adjacent thereto are connected to each other. The tip of the center side of each of the inductors L4A and L4B is extended through up to the opposite face of the first insulating substrate 15 through via holes 21 and 23.

A part of the three inductors L1, L3, L5 is formed into a quadrilateral spiral shape on one side (upper surface) of the second insulating substrate 25 formed of the same material and in the same shape as the first insulating substrate 15, and is formed in the same dimension and with the same pitch section as the inductors L0B, L4A, and L4B.

A part of the inductors L1, L3, L5 on the second insulating substrate 25 is alternately wound reversely, and is formed so as to regionally stacked on the inductors L0B, L4A, and L4B. The peripheral tips of the inductors L1, L3, L5 are extended through up to the opposite side (lower surface) of the second insulating substrate 25 through via holes 27, 29, and 31, and the tips of the center side become connection pads S2, S3, and S4.

On the one side (upper surface) of a third insulating substrate 33 formed of the same material and in the same shape as the first and second insulating substrates 15 and 25, remaining parts of the aforementioned three inductors L1, L3, L5 are formed into a quadrilateral spiral shape, and are formed in an almost the same dimension and with the same pitch sections as the inductors L0B, L4A, L4B.

Each of the inductors L1, L3, L5 on the third insulating substrate 33 is alternately wound reversely, regionally stacked on the inductors L1, L3, L5 on the second insulating substrate 25, and is formed in an electrically same winding direction in a profile of positive connection. Outer peripheral tips of the inductors L1, L3, L5 on the third insulating substrate 33 respectively become connection pads S5, S6, S7, and the tip of the center side is extended through up to the opposite side (lower surface) of the third insulating substrate 33 through via holes 35, 37, 39.

Specifically, individual inductors L1, L3, L5 are divided into two layers on the second and third insulating substrates 25 and 33, and connected to each other in series, to form substantial inductor of one section as will be described later.

Three inductors L2A, L2B, L6A are formed into a quadrilateral spiral shape on one side (upper surface) of a fourth insulating substrate formed of the same material and in the same shape as the first to three insulating substrates 15, 25, 33, and are formed in the same dimension and with the same pitch sections as the inductors L1, L3, L5.

The inductors L2A, L2B, L6A are respectively alternately wound reversely, and are formed in the electrically same winding direction so as to be regionally stacked on the inductors L1, L3, L5 on the third insulating substrate 33 in an appearance of positive connection. The tip of the center side of each inductor L1, L3, L5 on the third insulating substrate 33 is extended through up to the opposite side (lower surface) of the fourth insulating substrate 41 through via holes 43, 45, 47.

The peripheral tips of the inductor L2A and the inductor L2B adjacent thereto are mutually connected, and the peripheral tip of the inductor L6A adjacent to the inductor L2B is connected to an output terminal 49 formed on the other tip part in the longitudinal direction of the fourth insulating substrate 41.

Each inductor L0B, L4A, L4B of the first insulating substrate 15, each inductor L1, L3, L5 of the second and third insulating substrates 25 and 33, and each inductor L2A, L2B, L6A of the fourth insulating substrate 41 have almost same number of turns, and are formed by the conventionally known method including the connection parts thereof. Although a thickness is not shown for convenience, the first to fourth insulating substrates 15, 25, 33, 41 have a prescribed thickness of 0.1 mm, for example.

The first and second insulating substrates 15 and 25 are stacked on each other so that outer shapes thereof are mated with each other, and a part of the inductors L0B and L1, a part of the inductors L4A and L3, and a part of the inductors L4B and L5 are regionally stacked one another through the first insulating substrate 15.

The center side of the inductor L0B is connected to the connection pad S2 of the inductor L1 through the via hole 19, the center side of the inductor L4A is connected to the connection pad S3 of the inductor L3 through the via hole 21, and the center side of the inductor L4B is connected to the connection pad S4 of the inductor L5 through the via hole 23.

The third insulating substrate 33 is stacked on the second insulating substrate 25, so that the outer shapes thereof are mated with each other, and each part of the inductors L1, L3, and L5 are regionally stacked on the remaining inductors L1, L3, and L5 on the third insulating substrate 33 through the second insulating substrate 25, so as to connect to each connection pad S5, S6, S7 in series through mutual via holes 27, 29, and 31, to form each inductor L1, L3, and L5 of substantial one section.

The fourth insulating substrate 41 is stacked on the third insulating substrate 33 so that the outer shapes thereof are mated with each other, and a part (remaining part) of the inductor L1 and L2A, a part (remaining part) of the inductor L3 and L2B, and a part (remaining part) of the inductor L5 and L6A are regionally stacked one another.

In addition, the inductor L1 is connected to the center side of the inductor L2A through the via hole 35, the inductor L3 is connected to the center side of the inductor L2B through the via hole 37, and the inductor L5 is connected to the center side of the inductor L6A through the via hole 39, and thus the inductance element A according to the present invention is formed.

In each of the inductors L0B, L4A, and L4B of the first insulating substrate 15, fixed capacities C1, C4, C5 are respectively connected to the center side of the aforementioned each inductor in the vicinity of the via holes 19, 21, and 23. Also, in each of the inductors L2A, L2B, and L6A of the fourth insulating substrate 41, fixed capacities C2, C3, and C6 are connected to the center side of the aforementioned each inductor in the vicinity of the via holes 43, 45, and 47.

The other ends of each of the fixed capacities C1, C4, and C5 are commonly connected, and also the other ends of each of the fixed capacities C2, C3, and C6 are commonly connected, and thus the lumped constant type electromagnetic delay line having plural sections is constituted. FIG. 2 shows its equivalent circuit diagram.

Each fixed capacities C1, C4, C5, and each fixed capacities C2, C3, C6 are respectively constituted by a known method whereby a capacitor electrode and a ground common electrode are formed face-to-face on separate dielectric insulating substrates similar to the first to fourth insulating substrates 15, 25, 33, and 41, thereby integrating the structure in a plate-like shape by stacking on the first and fourth insulating substrates 25, although not specifically shown.

In the lumped constant type electromagnetic delay line with this structure, the inductor L1 of the second and third insulating substrates 25 and 33, the inductors L2A and L2B of the fourth insulating substrate 41, the inductor L3 of the second and third insulating substrates 25 and 33, the inductors L4A and L4B of the first insulating substrate 15, and the inductor L5 of the second and third insulating substrates 25 and 33 respectively correspond to the inductors of one section. Input and output side inductors L0B and L6A of the first and fourth insulating substrates 15 and 41 become a T-type termination to form a matching circuit of a half section.

Specifically, the inductance element A has the structure wherein the inductor L1 not divided in the horizontal direction, the first inductor L2A and the second inductor L2B divided in the horizontal direction, the inductor L3 not divided in the horizontal direction, the first inductor L4A and the second inductor L4B divided in the horizontal direction, and the inductor L5 not divided in the horizontal direction form each section, and are alternately arranged and electrically vertically connected.

In the electromagnetic delay line with this structure, a signal inputted from the input terminal 17 passes through the inductors L0B, L1 (L1), L2A, L2B, L3 (L3), L4A, L4A, L5 (L5), L6A in this order, and is outputted from the output terminal 25.

Next, an operation of the inductance element A with this structure will be explained.

The inductor L0B, which is a matching section of the input side, is connected with positive coupling to the inductor L1 of the following section.

The inductor of the following section that continues to the section formed by the inductor L1 is divided in the horizontal direction into the first inductor L2A and the second inductor L2B on the fourth insulating substrate 41, and only the first inductor L2A is arranged in the vertical positional relation with the inductor L1 of the preceding section and is connected thereto with positive coupling.

Meanwhile, the second inductor L2B is connected with positive coupling to the inductor L3 divided into two-layer structure on the second and third insulating substrates 25 and 33 in a vertical positional relation. The inductor of the following section that continues to the section formed by the inductor L3 is divided on the first inductor L4A and a second spiral inductor L4B of the first insulating substrate 15, and only the first inductor L4A is connected with positive coupling to the inductor L3 in the vertical positional relation.

The second spiral inductor L4B is connected with positive coupling to the inductor L5 formed into two layer structure on the second and third insulating substrates 25 and 33 in the vertical positional relation, and the section formed by the inductor L5 is connected with positive coupling to the inductor L5 in the vertical positional relation, and the section formed by the inductor L5 is connected with positive coupling to the inductor L6A of the output side of the following section in the vertical positional relation.

First, the section of the intermediate inductor L3 out of the inductors L1, L3, L5 of two-layer structure is focused. The inductor L3 is connected with positive coupling to the second inductor L2B of the preceding section in the vertical positional relation, and is also connected with positive coupling to the first inductor L4A of the following section in the vertical positional relation.

Specifically, the inductance element A of the present invention is arranged in the vertical positional relation, so that three inductors are connected with positive coupling in the vertical positional relation, that is, the second inductor divided in the horizontal direction in the preceding section of the section not divided, and the first inductor divided in the horizontal direction in the following section of the section not divided, are connected with positive coupling, with the section not divided in the horizontal direction placed therebetween.

It can be considered that the inductors L0B and L6A correspond to the first or second inductor of the section divided in the horizontal direction. Therefore, other inductors L1 and L5 of two layer-structures are also arranged in the same relation as the inductor L3. The lumped constant type delay line thus structured by plural sections has a continuous structure with the aforementioned relation.

In addition, in the aforementioned inductance element A, the relations between the inductors L0B and L1, between the inductors L1 and L2A, between the inductors L2B and L3, between the inductors L3 and L4A, between inductors L4B and L5 and the inductors L5 and L6A are in a coupling state between the inductor not divided and the inductor divided into about half. Therefore, each of the mutual inductances decreases by about half of the inductors not divided in a hierarchical relationship, and the coupling coefficient also decreases by about half.

Coupling coefficient a1 realized by this structure becomes a value close to the aforementioned desired positive value, when the thickness of the insulating substrates 15, 25, 33 is adjusted in a range from about 0.05 mm to 0.15 mm for example, although depending on the inductor.

Further, for example in FIG. 1, the inductance element A has a structure that the inductors of two sections are housed in an area region per each pattern of the inductors L0B, L4A, and L4B, when viewed in the horizontal direction from the first insulating substrate 15. This shows the structure that the inductors of six sections are housed which are twice the sections of the conventional structure wherein the inductor of one section per one pattern is housed.

Therefore, in the inductance element A of the present invention, housing sections per unit area become twice that of the conventional structure, and the thickness of the first to fourth insulating substrates 15, 25, 33, and 41 can be suppressed to be thin. The lumped constant type electromagnetic delay line using such an inductance element A is capable of obtaining an excellent delay characteristic, and also can be easily formed in a ultra-small type chip shape.

In addition, in the structure of the aforementioned inductance element A of FIG. 1, the coupling coefficient a1 becomes most desirable value, and the coupling coefficients a2 and a3 also become positive couplings. However, in this condition, the coupling coefficient a1 having most significant influence on the delay characteristic can be set in an optimum state, thereby exhibiting a large effect. Further, combined with the point that the housing section per unit area can be twice that of the conventional structure, there is an advantage of lessening the influence of positive coupling of the coupling coefficients a2 and a3.

Incidentally, the aforementioned inductance element A of FIG. 1 has the structure that each inductance of one section of the electromagnetic delay line is formed on one side of the first to fourth insulating substrates 15, 25, 33, and 41, and the first to fourth insulating substrates 15, 25, 33, and 41 are stacked on one another.

The inductance element A of the present invention may have the structure of forming the inductors of each section on mutually opposing surfaces of one sheet of dielectric insulating substrate, or forming the insulating film by CVD (Chemical Vapor Deposition) instead of the insulating substrate, and forming a spiral inductor with copper and aluminum material by sputtering, wherein the insulating substrate, insulating film, or insulating layer or the like can be arbitrarily selected.

The point is that it is preferable that the inductors forming each section of the electromagnetic delay line is formed in a spiral shape, and each inductor of one section is arranged in the vertical positional relation in series, so that the section divided and arranged into the first and second inductors in the horizontal direction and the section not divided are alternately and vertically connected, and the first inductor is connected with positive coupling to the preceding inductor not divided in the vertical positional relation in series. The second inductor of this section is connected with positive coupling to the following inductor of the section not divided in the vertical positional relation in series.

In addition, the aforementioned inductors of the section not divided in the horizontal direction are divisionally arranged in the vertical positional relation in series so as to be connected with positive coupling. Meanwhile, one of the inductors out of the aforementioned inductors of the section not divided in the horizontal direction is arranged in the vertical positional relation so as to be connected with positive coupling to the second inductor of the preceding section in series, and other inductor of this section is arranged in the vertical positional relation so as to be connected with positive coupling to the second inductor of the following section divided in the horizontal direction in series. In this structure, the inductance element A and the electromagnetic delay line can be easily formed by using the same shaped inductors L0B to L6A and the same shaped first to fourth insulating substrates 15, 25, 33, and 41, thus realizing a simple structure and manufacture.

Further, in the inductance element A of the present invention, the spiral shaped inductors L0B to L6A forming each section are not limited to a case of forming them with a plurality of number of turns.

When the inductance element A is used in the ultra-small delay line and a small delay time is realized, it becomes necessary to reduce the number of turns, and the inductors L0B to L6A can be formed with one turn or less than one turn. Meanwhile, when it is necessary to realize a large delay time, the number of turns of the inductors L0B to L6A is required to be increased.

In such a case, when an area for increasing the number of turns is not obtained, the number of layers is required to be increased. Specifically, the inductor of the section divided in the horizontal direction is not applied only to one layer structure but may be formed in a multi-layer structure of not less than two layers. The inductors of the section not divided in the horizontal direction can also be increased or decreased to one layer or not less than two layers.

The point is that one of the inductance values of the divided section may be formed in about half of the inductance values of the section not divided. For example, when the number of turns of each inductor of the divided section is half turn and the number of turns of the section not divided is one turn, the section not divided may be formed in one layer.

In addition, the aforementioned inductance element A has a six-section structure. However, when the electromagnetic delay line is commercialized as an electronic component, the inductance element A is generally formed in about a ten-section structure. Therefore, for example, as shown below, the number of sections of the inductance element A of the present invention may be increased or decreased.

FIG. 3 is a schematic plan view showing other embodiment of the inductance element A according to the present invention.

In FIG. 3, designation marks U1, U2, U3, U4, U5, and U6 show the inductors L0B to L6A formed on the first to fourth insulating substrates 15, 25, 33, and 41 of FIG. 1, and an inductance unit in a state of being viewed in the horizontal direction from the first insulating substrate 15.

Specifically, the inductance unit U1 is formed by defining the inductors L0B, L1 (L1), and L2A formed on the first to fourth insulating substrates 15, 25, 33, and 41 of FIG. 1 as one unit, inductance unit U2 is formed by defining the inductors L4A, L3 (L3), and L2B as one unit, and the inductance unit U3 is formed by defining the inductors L4B, L5 (L5), and L6A as one unit.

The inductance units U4, U5, and U6 are formed similarly and correspondingly to each of the inductance units U1, U2, and U3.

FIG. 3 (1) shows the structure shown in the aforementioned FIG. 1 by the inductance units U1 to U3, and the inductance units U1 to U3 are linearly vertically connected in one direction.

Meanwhile, FIG. 3 (2) shows the structure wherein the inductance units U1 to U6 are alternately arranged in a zigzag manner on a first virtual line P and on a second virtual line Q positioned in parallel thereto at a prescribed space, and are vertically connected to the first to fourth insulating substrates (not shown) with large dimension formed of the same material as that of the first to fourth insulating substrates 15, 25, 33, and 41. The inductors L0B to L6A or the inductor corresponding thereto are formed same as the inductor of FIG. 1.

Further, FIG. 3 (3) shows the structure wherein the inductance unit U1 is arranged on the first virtual line P, and the inductance units U2 and U3 are arranged on the second virtual line Q, the following inductance units U4 and U5 are arranged on the first virtual line P, and the inductance unit U6 is arranged on the second virtual line Q, and these inductors are virtually connected to the first to fourth insulating substrates (not shown) with large dimension.

Namely, two inductance units are arranged in a rectangular form on the first and second virtual lines P and Q, and one inductance unit is arranged on the input side and the output side, respectively.

In the structure shown in FIGS. 3 (1) to (3), an inputted electric signal is outputted through the inductance units U1 to U3 or U1 to U6 in the order of arrows, in the structure of FIG. 3 (1), a six-section structure is provided wherein three inductors of two sections are vertically connected, and in the structure of FIGS. 3 (2) and (3), twelve-section structure is provided wherein six inductors of two sections are vertically connected.

When the electromagnetic delay line is constituted by using such an inductance element A, a plurality of section formation such as six sections and twelve sections are easy, and a large delay time can be realized.

Incidentally; in the inductance units U1 to U6 using the inductors L0B to L6A of FIG. 1, winding directions of the inductors L0B to L6A become reversed directions to each other between the inductance units U1 and U2, and also between the inductance units U2 and U3. However, the inductors L0B to L6A can be deformed, so that all the inductance units U1 to U6 have the same directions.

In this case, inter-inductance units U1 and U2, and inter-inductance units U2 and U3 become negative connections, and therefore when the inductor has the same number of turns, the delay time is more reduced than the structure of FIG. 1. However, in an opposite way, a positive value of the coupling coefficient a2 is decreased.

Preferably, the value of the coupling coefficient a2 is supposed to be negative. However, when the coupling coefficient a2 has a positive value, although the delay time is reduced at a small value, the delay characteristic is improved.

The present invention can also have the structure wherein the inductance units U1 to U6 are dispersed and arranged in the first, second, and third virtual lines.

### INDUSTRIAL APPLICABILITY

The inductance element of the present invention is preferably used in a lumped constant type electromagnetic delay line for delaying an electric signal in an electronic component such as computer.

### BRIEF DESCRIPTION OF THE DRAWINGS

FIG. 1 is an exploded perspective view showing an embodiment of an inductance element of an electromagnetic delay line and the electromagnetic delay line according to the present invention.

FIG. 2 is an equivalent circuit of the electromagnetic delay line shown in FIG. 1.

FIG. 3 is a schematic plan view showing other embodiment of the inductance element according to the present invention.

FIG. 4 is an exploded perspective view showing a conventional distribution constant type delay line.

FIG. 5 is a general equivalent circuit diagram of the lumped constant type delay line.

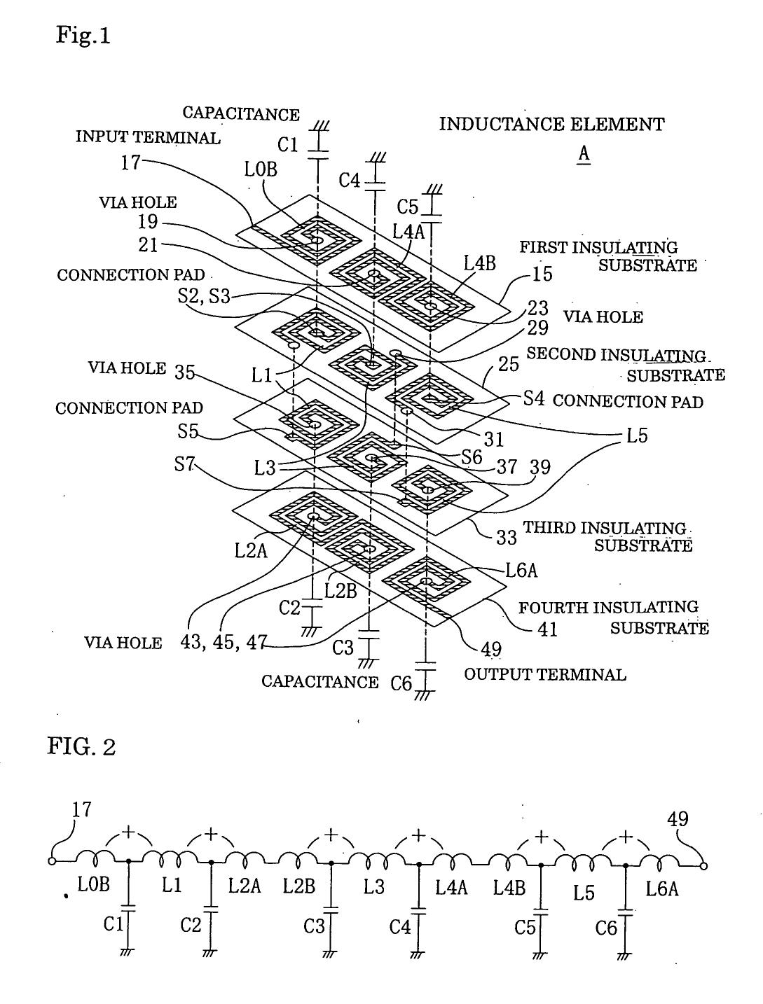

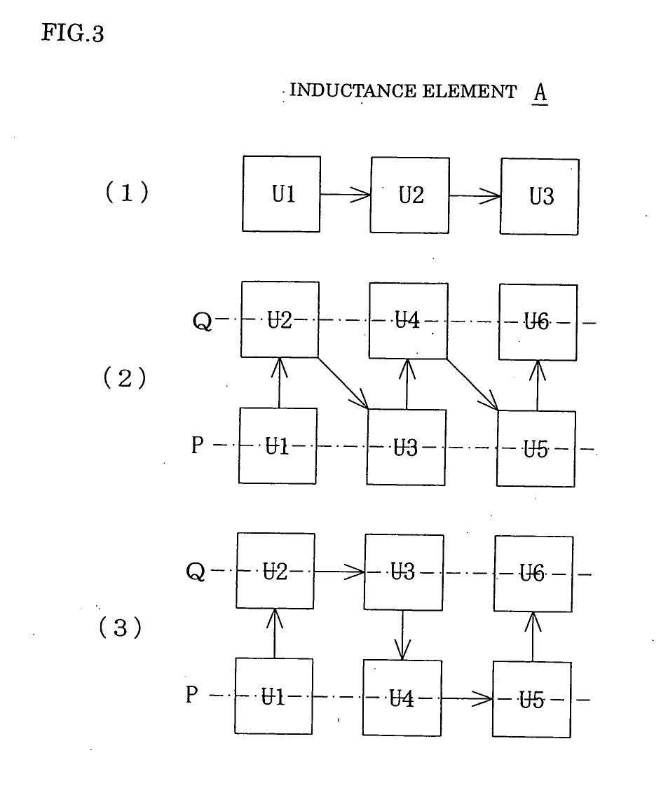

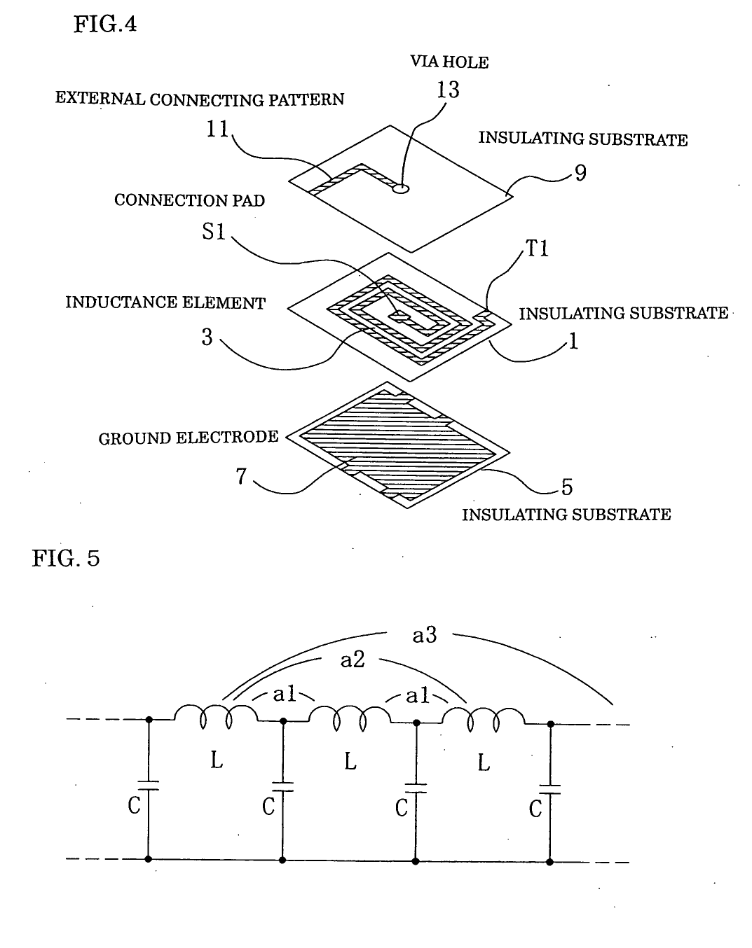

### DESCRIPTION OF THE SIGNS AND NUMERALS

1, 5, 9 Insulating substrate
3, A Inductance element
7 Ground electrode
11 External connecting pattern
13, 19, 21, 23, 27, 29, 31, 35, 37, 39, 43, 45, 47, via hole (through hole)
15 First insulating substrate
17 Input terminal
25 Second insulating substrate
33 Third insulating substrate
41 Fourth insulating substrate
49 Output terminal
C, C1, C2, C3, C4, C5, C6, Capacitance (Fixed capacitance)
L, L0B, L1, L3, L5, L6A Inductor
L2A, L4A, Inductor (First inductor)
L2B, L4B, Inductor (Second inductor)
Q First virtual line
P Second virtual line
S1, S2, S3, S4, S5, S6, S7 Connection pad
T1 Tip
U1, U2, U3, U4, U5, U6 Inductance unit

1. An inductance element of an electromagnetic delay line in a lumped constant type electromagnetic delay line having a plurality of sections formed of an inductance element which is formed by connecting a plurality of inductors in series, and capacities which are vertically connected to each connection point in a ladder shape,
wherein the inductors of the electromagnetic delay line are formed in a spiral shape, the inductors of one section are formed by alternately and vertically connecting the section divided and arranged into a first and second inductors in a horizontal direction and the section not divided, the first inductor is arranged in a vertical positional relation so as to be connected with positive coupling to the inductor of the preceding section not divided in series, and the second inductor of the section is arranged in the vertical positional relation so as to be connected with positive coupling to the inductor of the following section not divided in series, and the inductors as two sections of delay line are arranged in the vertical positional relation.

2. The inductance element of the electromagnetic delay line according to claim 1, wherein the inductors of two sections formed between the section not divided in the horizontal direction and the preceding and the following sections divided in the horizontal direction, with the section not divided placed there between, are connected with positive coupling in the vertical positional relation, and this structure is defined as one inductance unit, and a plurality of inductance units thus constituted are vertically connected and adjacent inductance units are dispersed and arranged in first, second virtual lines.
